(19) United States
(12) Patent Application Publication
(10) Pub. No.: US 2026/0177642 A1
(43) Pub. Date: Jun. 25, 2026

(54) SYSTEM AND METHOD FOR ESTIMATING A CHARACTERISTIC OPERATING QUANTITY OF A POWER CONVERTER

(71) Applicant: Commissariat à l'Energie Atomique et aux Energies Alternatives, Paris (FR)

(72) Inventors: Youssof FASSI, Grenoble Cedex 9 (FR); Vincent HEIRIES, Grenoble Cedex 9 (FR); Jérôme BOUTET, Grenoble Cedex 9 (FR); Sébastien BOISSEAU, Grenoble Cedex 9 (FR)

(73) Assignee: Commissariat à l'Energie Atomique et aux Energies Alternatives, Paris (FR)

(21) Appl. No.: 19/427,356

(22) Filed: Dec. 19, 2025

(30) Foreign Application Priority Data
Dec. 19, 2024 (FR) FR2414776

(51) Int. Cl. G01R 31/62

(52) U.S. Cl. CPC G01R 31/62

(57) ABSTRACT

A method for estimating a characteristic operating quantity of a candidate power converter comprising a transformer, the method being executed by data processing circuitry and comprising acquiring a signal representative of the vibrations emitted by the transformer; and estimating the characteristic operating quantity of the candidate power converter based on the signal representative of the detected vibrations.

The present invention concerns the field of signal processing and neural network optimization, in particular methods and systems for compressing and analyzing high-dimensional ultrasonic data for predicting a characteristic operating quantity in industrial applications.

### PRIOR ART

To monitor the operation of a converter, it is necessary to measure at least one characteristic operating quantity. As an example of such a characteristic operating quantity, the efficiency of a converter is a well-known quantity which is calculated as the ratio of the output power to the power consumed at the input.

Measuring the efficiency of the power converters has several challenges. The current methods typically require sensors to measure input and output currents and voltages, which is invasive and necessitates appropriate galvanic isolation at high current and voltage values and adds bulk to the system. Furthermore, accurately measuring the output power of complete systems can be difficult, often requiring approximations of losses using simulations. These simulations can lack accuracy due to system complexity and the variability of operating conditions. Other methods use calorimetric measurements, but these are only used for offIine estimations.

The present invention aims to resolve all or part of the drawbacks mentioned above.

### DISCLOSURE OF THE INVENTION

To this end, the present invention concerns a method for estimating a characteristic operating quantity of a candidate power converter comprising a transformer, the method being executed by a data processing unit and comprising the following steps:
acquiring a signal representative of the vibrations emitted by the transformer;
estimating the characteristic operating quantity of the candidate power converter based on the signal representative of the detected vibrations using an inference processing of a characteristic operating quantity based on an artificial intelligence model,
the method comprising a phase of preliminarily learning the artificial intelligence model for estimating a characteristic operating quantity of a candidate power converter, comprising the following steps:
acquiring a signal representative of the vibrations emitted by the transformer of a reference converter,
acquiring at least one signal representative of at least one characteristic electrical quantity of a reference converter,
determining a calculated efficiency value of the reference converter based on the at least one signal representative of at least one electrical quantity;
estimating an estimated value of a characteristic operating quantity of the reference converter based on the signal representative of the vibrations emitted by the reference transformer;
calculating a first evaluation function taking into account the calculated value of a characteristic operating quantity of the reference converter and the estimated value of a characteristic operating quantity (f) of the reference converter
adjusting parameters of the artificial intelligence model using the first evaluation function.

Thanks to these arrangements, it is possible to carry out a non-invasive estimation of a characteristic operating quantity of a power converter, in a manner adapted to the converters comprising a transformer which generates vibrations. In particular, this system is adapted to AC/DC converters with a transformer.

This approach makes it possible to overcome the limitations of traditional invasive sensors and simulation-based approximations, thus offering an accurate and non-invasive solution for measuring a characteristic operating quantity.

According to one possibility, the first evaluation function is a loss function

According to one implementation, the estimation method comprises, prior to the estimation of a characteristic operating quantity, a step of compressing the data of the signal representative of the detected vibrations.

The exploitation of vibration signals generates large involved volumes of data, which pose significant challenges for storage and analysis. Data compression techniques offer promising solutions to these data management problems.

According to one implementation, the estimation method further comprises a step of performing analog-to-digital conversion of the signal representative of the vibrations into a digital signal representative of the detected vibrations.

According to one implementation, the step of compressing the data of the signal representative of the detected vibrations is carried out using a feature extraction module.

According to one implementation, the feature extraction module is a convolutional encoder.

Deep learning models such as convolutional neural networks (CNNs) are used for faster training and inference.

According to one embodiment, convolutional layers with padding are used.

The CNN-based autoencoders can efficiently compress high-dimensional data while preserving essential features.

According to one implementation, convolution layers with large strides are used.

This approach enables high-quality compression of high-frequency signals. This approach preserves the integrity of important features of the ultrasound data, ensuring accurate and efficient processing.

According to one implementation, the artificial intelligence model comprises a neural network comprising fully connected layers.

Thus, the neural network architecture combines convolutional autoencoders with fully connected layers to compress and analyze ultrasonic data in a multitasking manner.

According to another possibility, the step of estimating a characteristic operating quantity of the power converter uses a spectral analysis method.

According to one implementation, the estimation step comprises the following sub-steps:
a first step of transforming the signal representative of the vibrations in order to obtain a frequency-domain representation,
a second step of determining at least one ratio of the energy contained in at least one frequency band to the total energy of the signal according to the frequency-domain representation,
a third step of comparing the ratios to experimentally established reference values in order to estimate the value of the characteristic operating quantity of a converter associated with the ratios.

According to one embodiment, the carried-out transformation is a Fourier transform, notably to obtain a power spectral density. This frequency-domain representation makes it possible to highlight the spectral characteristics related to a plurality of power ratings and values of the characteristic operating quantity of a converter.

Indeed, each power rating or value of the characteristic operating quantity of a converter induces a specific spectral signature, manifested by a particular distribution of energy in a plurality of frequency bands.

The bands are selected so as to discriminate between the values of the considered power ratings. By calculating the ratio of the energy contained in each of these bands to the total energy of the signal, it is possible to characterize the power ratings.

According to one implementation, the signal representative of the vibrations is an ultrasonic signal.

According to one implementation, the ultrasonic probe is placed at a fixed distance from the transformer of the power converter, where the kernel vibrates in the presence of a magnetic field and transmits ultrasonic data to the probe through the air.

The ultrasonic probes detect high-frequency sound waves (compression waves) propagating through a medium. These waves are then converted into electrical signals through a transducer and can be processed to gather information about the emitting source or the properties of the medium. Unlike electrical sensors, these probes can be placed at a distance, reducing the risk of interference and the need for extensive insulation.

According to one implementation, the estimation method comprises a step of conditioning and/or amplifying the signal representative of the detected vibrations.

According to one implementation, the amplifier is an analog amplifier configured to provide an amplified version of the signal representative of the detected vibrations to the analog-to-digital converter.

According to one implementation, the analog-to-digital conversion step carries out sampling with a frequency greater than 300 kHz, in particular with a frequency greater than 400 KHz.

Thanks to these arrangements, it is possible to accurately identify phenomena within a frequency band between 80 and 130 kHz. According to one embodiment, a frequency of less than 600 KHz is selected. For example, a frequency in the range of 100 KHz can be selected.

According to one implementation, the signal representative of the detected vibrations processed by the estimation step or by the compression step is configured as samples comprising a data set corresponding to a detection duration between 1 and 10 cycles of an input voltage or an input current of the reference converter, in particular between 3 and 8 cycles.

According to one implementation, a sample corresponds to a time sequence/frame of the signal representative of the detected vibrations.

According to one implementation, the detection duration is between 1 and 200 ms, in particular between 50 and 150 ms.

According to one exemplary implementation, the detection duration is in the range of 100 ms.

According to one exemplary implementation, the characteristic operating quantity of a converter is an efficiency of the converter.

According to other variants, the characteristic operating quantity of a converter can be, for example, the output power, the state of health or the rectified current passing through the transformer, instead of, or in addition to, the efficiency.

According to one exemplary implementation, the learning phase also comprises the following step:
synchronizing the signal representative of the detected vibrations and the signal representative of at least one electrical quantity.

The method thus comprises a mechanism to align electrical and ultrasonic measurements, thus ensuring accurate data correlation.

According to one exemplary implementation, the method further comprises the following steps:
compressing the signal representative of the detected vibrations using a feature extraction module, the compression step being carried out before the step of estimating the estimated value of a characteristic operating quantity (1) of the reference converter in order to provide a version of the signal representative of the detected vibrations in a latent space;
reconstructing a reconstructed signal representative of the detected vibrations from the version of the signal representative of the detected vibrations in a latent space;
calculating a second evaluation function taking into account the reconstructed signal representative of the detected vibrations, and the version of the signal representative of the detected vibrations in a latent space;
adjusting the parameters of the feature extraction module using the second evaluation function.

By incorporating information of the latent space, which can be considered as frequency domain information in the loss function, the system significantly reduces reconstruction errors and improves the accuracy of predicting a characteristic operating quantity compared to the traditional methods. This dual approach ensures that the compressed representation is both efficient and informative, which makes it possible to obtain better performance in real-time applications.

According to one exemplary implementation, the estimation method comprises a step of adjusting the parameters of the feature extraction module, and the step of adjusting parameters of the artificial intelligence model that are carried out simultaneously.

According to one implementation, the step of calculating a first evaluation function and the step of adjusting parameters of the artificial intelligence model on the one hand, the step of reconstructing a reconstructed signal representative of the detected vibrations, the step of calculating a second evaluation function and the step of adjusting the parameters of the feature extraction module on the other hand are carried out simultaneously.

According to one implementation, the estimation method comprises the steps of a learning method as defined previously.

The invention also concerns a method for controlIing or commanding a power converter comprising the steps of a method for estimating a characteristic operating quantity of a candidate converter as defined above, and comprising the following steps:
detecting a decrease in the efficiency of the candidate converter;
issuing an alert to a user and/or
activating a degraded operating mode of the candidate converter;

The invention also concerns a system for estimating a characteristic operating quantity of a power converter comprising at least one transformer, the system including a processing unit comprising:
an acquisition module comprising a vibration detector configured to detect vibrations emitted by the transformer and to provide a signal representative of the detected vibrations;
a module for estimating a characteristic operating quantity (f) of the power converter based on the signal representative of the detected vibrations; The processing unit being configured to implement a method according to any one of claims 1 to 11

According to one embodiment, the vibration detector is an ultrasonic probe.

According to one embodiment, the ultrasonic probe is placed at a fixed distance from the transformer of the power converter, where the kernel vibrates in the presence of a magnetic field and transmits ultrasonic data to the probe through the air.

According to another possibility, the vibration detector is a piezoelectric detector.

According to one embodiment, the vibration detector is disposed facing the transformer of the converter.

According to one embodiment, the acquisition module comprises a plurality of vibration detectors.

According to one embodiment, the system comprising an analog-to-digital converter configured to convert the signal representative of the detected vibrations into a digital signal representative of the detected vibrations;

The present invention also concerns a computer program product comprising code instructions for the execution of a previously defined method, when said program is executed on a computer.

The present invention also concerns a storage means readable by computer equipment on which is recorded a computer program product comprising code instructions for the execution of a method as defined above.

### BRIEF DESCRIPTION OF THE FIGURES

The invention will be described with reference to the following figures, which are given for illustrative purposes only and are not reproduced to scale. In these figures, the same reference numerals designate the same elements.

FIG. 1 represents a system according to the invention in a learning configuration;

FIG. 2 represents a system according to the invention in an inference configuration;

FIG. 3 represents the flowchart of a learning method according to a first embodiment of the invention;

FIG. 4 represents the flowchart of an estimation method according to a first embodiment of the invention;

FIG. 5 represents a method for controlIing or commanding a power converter according to the invention;

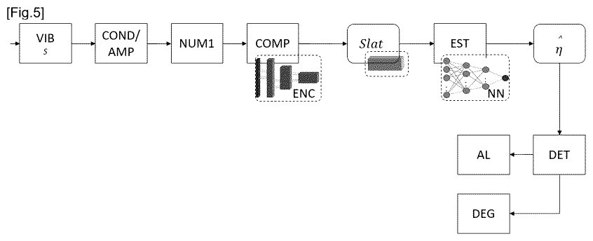

FIG. 6 represents the flowchart of a learning method according to a second embodiment of the invention;

FIG. 7 represents the comparison between the estimation results and the measurement results.

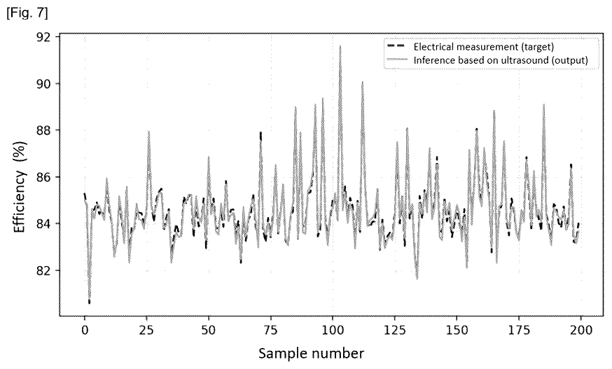

### DETAILED DESCRIPTION

A first embodiment of the invention, implementing a system and a method based on learning and inference processing of a characteristic operating quantity based on an artificial intelligence model (NN), will be described first.

### System in Learning Configuration

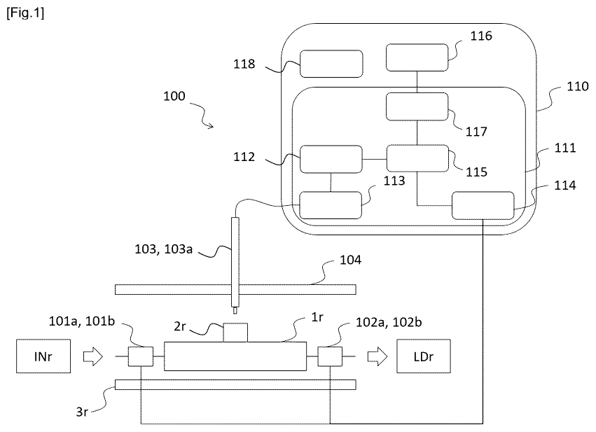

According to a first embodiment, as represented in FIG. 1 in a learning configuration, a system 100 for estimating a characteristic operating quantity of a converter is associated with a reference power converter 1r. This reference power converter 1r comprises, particularly in the case of an AC/DC converter, one or several transformers 2r. The reference power converter 1r is attached to a first support 3r. The converter ensures the conversion between an input power supply INr and an adaptive output load LDr.

The estimation system 100 comprises, in a learning configuration, an input current sensor 101a and an input voltage sensor 101b of the reference power converter 1r disposed at the input of the reference power converter, and an output current sensor 102a and an output voltage sensor 102b of the reference power converter 1r disposed at the output of the reference power converter.

The estimation system 100 further comprises a vibration detector 103. In the example represented in FIG. 1, the vibration detector is an ultrasonic probe 103a, secured to a second support 104. In particular, the second support 104 is fixed relative to the first support 3. The probe is disposed facing the transformer 2 at a fixed distance. The transformer 2r comprises a kernel that vibrates in the presence of a magnetic field, which generates and transmits an ultrasonic signal to the probe through the air.

According to one example, the ultrasonic probe is positioned at a fixed distance between 6 and 15 cm from the power converter and above the transformer, so that the probe captures complete acoustic signals without interfering with the operation of the system. Accurate positioning of the probe is obtained thanks to a first support 3 comprising a calibrated mounting system that maintains constant distance and angle relative to the power converter 1r.

The estimation system 100 comprises a data processing unit 110 which comprises a data acquisition module 111 configured to acquire a signal representative of the vibrations detected by the detector 103 and a signal representative of the electrical quantities of voltage and current at the input and output.

In particular, the data acquisition module 111 comprises:
a sub-module 112 for acquiring a signal from the vibration detector 103, which can be associated with a vibration signal conditioner 113 and, in particular, an ultrasonic signal conditioner in the case where the vibration detector is an ultrasonic probe 103a; and
a sub-module 114 for acquiring signals representative of the electrical quantities of voltage and current at the input and output from sensors 101a, 101b, 102a and 102b.

The acquisition module 111 also comprises an analog-to-digital converter 115 configured to convert the signal representative of the detected vibrations into a digital signal representative of the detected vibrations, and similarly, the signals representative of the electrical quantities into digital signals. According to one possibility, the analog-to-digital converter 115 may comprise two converters, which are included in the sub-modules 112 and 114, respectively.

The data processing unit 110 also comprises a module for estimating a characteristic operating quantity of the power converter 116 which collects and processes the data provided by the analog-to-digital converter 115.

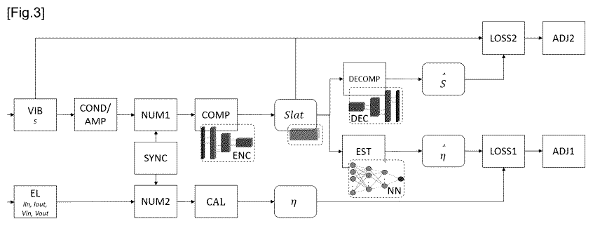

The module for estimating a characteristic operating quantity implements, in the learning configuration, method steps which are described below with reference to FIG. 3 based on the signals representative of the vibrations and the signals representative of the electrical quantities.

The system also comprises a synchronization module 117 located downstream of the analog-to-digital converter 115, which aligns the timing of the capture or acquisition of the signals representative of the vibrations with the capture or acquisition of the electrical measurements of the power converter. The network then efficiently learns the connection between the ultrasonic signals and the efficiency of the power converter, allowing for accurate deduction of the efficiency.

The data processing unit 110 also comprises a memory 118.

### System in Inference Configuration

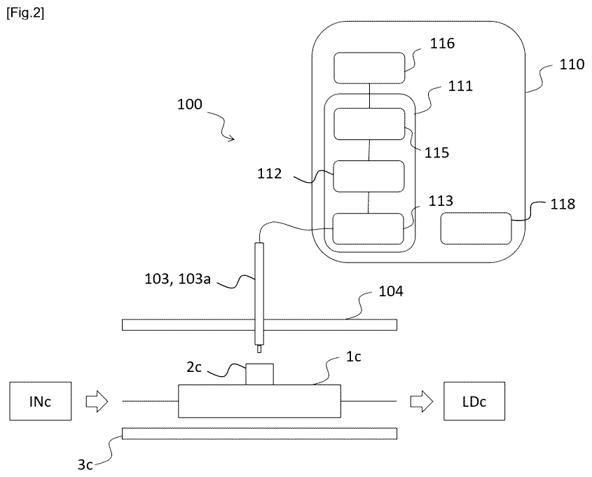

As represented in FIG. 2 in an inference configuration, a system 100 for estimating a characteristic operating quantity of a converter is associated with a candidate power converter 1c of the same type as the reference converter 1r. This candidate power converter 1c comprises, particularly in the case of an AC/DC converter, one or several transformers 2c. The reference power converter 1 is attached to a first support 3c. The converter ensures the conversion between an input power supply INc and an output load LDc.

The estimation system 100 comprises, as in the learning configuration, a vibration detector 103. In the example represented in FIG. 1, the vibration detector is an ultrasonic probe 103a, secured to a second support 104. In particular, the second support 104 is fixed relative to the first support 3r. The probe is disposed facing the transformer 2 at a fixed distance. The transformer 2r comprises a kernel that vibrates in the presence of a magnetic field, which generates and transmits an ultrasonic signal to the probe through the air.

In the inference configuration, the system does not implement electrical quantity sensors, unlike the learning configuration.

Similar to the learning configuration, according to one example, the ultrasonic probe is positioned at a fixed distance between 6 and 15 cm from the power converter and above the transformer, so that the probe captures complete acoustic signals without interfering with the operation of the system. Accurate positioning of the probe is obtained thanks to a first support 3 comprising a calibrated mounting system that maintains constant distance and angle relative to the power converter.

The estimation system 100 also comprises a data processing unit 110 which comprises a data acquisition module 111 configured to acquire a signal representative of the vibrations detected by the detector 103.

Unlike the learning configuration, the data processing unit 110 does not have to process signals representative of the electrical quantities.

Thus, in the inference configuration, the data acquisition module 111 comprises a sub-module 112 for acquiring a signal from the vibration detector 103, which can be associated with a vibration signal conditioner 113 and in particular an ultrasonic signal conditioner in the case where the vibration detector is an ultrasonic probe 103a.

The acquisition module 111 also comprises an analog-to-digital converter 115 configured to convert the signal representative of the detected vibrations into a digital signal representative of the detected vibrations.

The data processing unit 110 also comprises a module for estimating a characteristic operating quantity—for example the efficiency—of the power converter 116 which collects and processes the data provided by the analog-to-digital converter 115.

The data processing unit 110 also comprises a memory 118.

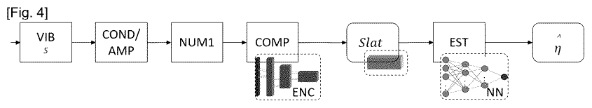

The module for estimating a characteristic operating quantity implements, in the inference configuration, method steps which are described below with reference to FIG. 4 based on the signals representative of the vibrations but without having to process data relating to the signals representative of the electrical quantities.

In the inference configuration, the synchronization module is not present.

Thus, in inference mode, the estimation system is simpler than in the learning mode, and does not require an invasive electrical measurement sensor in the converter.

### Learning Method

As represented in FIG. 3, the learning method, executed by the data processing unit 100, comprises acquisition steps, and in particular:
a step VIB of acquiring a signal S representative of the vibrations emitted by the transformer 2r of the reference converter 1r; and
a step EL of acquiring signals representative of the characteristic electrical quantities of a reference converter 1r.

The signals representative of the electrical quantities comprise, in particular:
an input current signal Iin provided by the input current sensor 101a;
an input voltage signal Vin provided by the input voltage sensor 101b;
an output current signal Iout provided by the output current sensor 102a; and
an output voltage signal Vout provided by the output voltage sensor 102b.

The method may comprise a step COND/AMP for conditioning and/or amplifying the signal S representative of the vibrations carried out by the vibration signal conditioner 113. The amplification is thus carried out in an analog manner.

The method comprises a step SYNC for synchronizing the signal S representative of the vibrations and the signals representative of the electrical quantities Vin, Vout, Iin, Iout. This step can be carried out by the synchronization module 115. The synchronization step makes it possible to align the electrical and vibration measurements, thus ensuring accurate data correlation.

The learning method then comprises a step NUM2 of performing analog-to-digital conversion of the signals representative of the electrical quantities Vin, Vout, Iin, Iout, which can be carried out by the sub-module 114 of the analog-to-digital converter 111, followed by a determination by calculation CAL of a calculated efficiency value of the converter η based on the signals representative of the electrical quantities Vin, Vout, Iin, Iout. In particular, the efficiency is calculated as the ratio of the output power to the power consumed at the input:

$$η = ( I out \times V out ) / ( I in \times V in )$$

At the same time, the method comprises steps of processing the signal S representative of the vibrations.

In particular, the learning method comprises a step of performing analog-to-digital conversion NUM1 of the signal S representative of the vibrations into a digital signal representative of the detected vibrations. This step can be carried out by the sub-module 112 of the analog-to-digital converter 111. According to one exemplary embodiment, the analog-to-digital conversion step carries out sampling with a frequency greater than 300 kHz, in particular with a frequency greater than 400 KHz. According to one embodiment, a frequency of less than 600 KHz is selected. For example, a frequency in the range of 500 KHz can be selected. It is thus possible to accurately identify phenomena within a frequency band between 80 and 130 KHz.

In a compression step COMP, the digital version of the signal S can then be compressed by an autoencoder so as to provide a transformed version Slat of the vibration data S in a latent space.

In particular, according to one exemplary implementation, a convolutional autoencoder is used with a stride ranging from 2 to 8 and a kernel size ranging from 3 to 11 to compress the ultrasonic data. The autoencoder reduces the dimensionality of the data by a factor ranging from 8 to 128, while the decoder reconstructs a reconstructed signal S estimating the original signal S.

The processed samples of the signal S correspond to a time sequence or frame of the signal representative of the detected vibrations. In particular, the samples comprise a data set corresponding to a detection duration between 1 and 10 cycles of an input voltage of the converter, in particular between 3 and 8 cycles. According to exemplary embodiments, the detection duration is between 1 and 20 ms, in particular between 5 and 15 ms. In particular, according to one exemplary embodiment, the detection duration is in the range of 10 ms.

For the autoencoder, a convolutional neural network (CNN) is used for fast training and inference. Convolutional layers with padding and large strides are used for high-quality compression of high-frequency signals. This approach preserves the integrity of important features of the vibration data, ensuring accurate and efficient processing.

The method comprises a step EST of estimating an estimated value of a characteristic operating quantity of the converter, for example the efficiency, based on the signal S representative of the vibrations emitted by the transformer 2c of the reference converter 1c. The estimation is carried out using a neural network, in particular a neural network comprising fully connected layers.

The method then comprises a step LOSS1 of calculating a first loss function taking into account the calculated value n of the efficiency of the reference converter 1r and the estimated value of the efficiency î of the converter.

Subsequently, a first adjustment step ADJ1 is carried out, in which parameters of the neural network NN are adjusted based on the calculation of the first loss function.

The method also includes a step DECOMP of decompressing the transformed vibration data Slat in the latent space, so as to reconstruct vibration data S.

Next, a second loss function LOSS2 is calculated based on the reconstructed vibration data, the signal of the vibration data S, but also the transformed vibration data in the latent space.

Thus, in a second adjustment step ADJ2, an adjustment of the encoder/decoder parameters is carried out.

By incorporating frequency domain information into the loss function, the system significantly reduces reconstruction errors and improves the accuracy of predicting the efficiency compared to traditional methods. This dual approach ensures that the compressed representation is both efficient and informative, which makes it possible to obtain better performance in real-time applications.

The steps of decompression DECOMP, calculation of the first loss function LOSS1 and adjustment of the encoder ADJ1 on the one hand and the steps of estimation EST, calculation of the second loss function LOSS2 and adjustment of the neural network ADJ2 on the other hand can be carried out simultaneously.

The learning method thus enables multitasking with two heads: one for the reconstruction of the signal S and the other for efficiency inference. This design ensures that the compressed representation Slat is optimized for both tasks.

The steps of the learning method can be carried out in a variety of input/output voltage and input/output current configurations, with one or several converters exhibiting a nominal or degraded operating state, in order to enable effective learning. For example, learning can be performed with a single converter and by applying a load varying between 80% and 120% of the rated load of the converter making it possible to achieve the rated power.

The learning carried out with one type of converter can potentially be valid for other types of converters, using transfer learning techniques.

### Estimation and Control/Command Method

Once the learning method has been carried out, according to one implementation represented in FIG. 4, a method for estimating a characteristic operating quantity, in particular the efficiency, of a candidate power converter 1c executed by the data processing unit 110 comprises firstly a step VIB of acquiring a signal S representative of the vibrations emitted by a transformer 2c of the candidate converter 1c.

A step COND/AMP of conditioning and/or amplifying the signal representative of the detected vibrations can then be carried out.

Subsequently, a step NUM1 of performing analog-to-digital conversion of the signal S representative of the vibrations into a digital signal representative of the detected vibrations is performed. Amplification is carried out in an analog manner by the conditioning module 113 to provide an amplified version of the signal representative of the detected vibrations in the analog-to-digital conversion step NUM1.

This step can be carried out by the sub-module 112 of the analog-to-digital converter 111. As previously indicated for the learning method, according to one exemplary embodiment, the analog-to-digital conversion step carries out sampling with a frequency greater than 300 kHz, in particular with a frequency greater than 400 KHz. According to one embodiment, a frequency of less than 600 KHz is selected. For example, a frequency in the range of 500 KHz can be selected. It is thus possible to accurately identify phenomena within a frequency band between 80 and 130 KHz.

In a compression step COMP, the digital version of the signal S can then be compressed by an autoencoder so as to provide a transformed version Slat of the data of the signal representative of the detected vibrations S in a latent space.

In particular, according to one exemplary implementation and similarly to the learning method, a convolutional autoencoder is used with a stride ranging from 2 to 8 and a kernel size ranging from 3 to 11 to compress the ultrasonic data. The autoencoder reduces the dimensionality of the data by a factor ranging from 8 to 128.

As mentioned for the learning method, the processed samples of the signal S correspond to a time sequence or frame of the signal representative of the detected vibrations. In particular, the samples comprise a data set corresponding to a detection duration between 1 and 10 cycles of an input voltage of the converter, in particular between 3 and 8 cycles. According to exemplary embodiments, the detection duration is between 1 and 20 ms, in particular between 5 and 15 ms. In particular, according to one exemplary embodiment, the detection duration is in the range of 10 ms.

The autoencoder, which was the object of the learning method comprising a convolutional neural network (CNN), is used for compression. Convolutional layers with padding and large strides are used for high-quality compression of high-frequency signals.

A step EST of estimating an estimated value of a characteristic operating quantity \hat{η} of the converter 1c is carried out based on the signal S representative of the vibrations emitted by the transformer 2c of the candidate converter 1c. The estimation is carried out using the neural network trained during the learning method, in particular a neural network comprising fully connected layers.

Thanks to these arrangements, it is possible to carry out a non-invasive estimation of a characteristic operating quantity of a power converter, in a manner adapted to the converters comprising a transformer that generates vibrations. In particular, this system is adapted for AC/DC converters with a transformer.

This approach makes it possible to overcome the limitations of traditional invasive sensors and simulation-based approximations, thus offering an accurate and non-invasive solution for measuring a characteristic operating quantity.

The method aims to estimate the efficiency of power converters. It combines a non-invasive ultrasonic probe with neural network-based inference processing of a characteristic operating quantity. The ultrasonic probe is placed at a fixed distance from the transformer of the power converters, where the kernel vibrates in the presence of a magnetic field and transmits ultrasonic data to the probe through the air. The system also incorporates synchronization mechanisms to align the electrical and ultrasonic measurements, thus ensuring accurate data correlation. This approach makes it possible to overcome the limitations of traditional invasive sensors and simulation-based approximations, thus offering an accurate and non-invasive solution for measuring a characteristic operating quantity.

The method also introduces a neural network architecture that combines convolutional autoencoders with fully connected layers to compress and analyze ultrasonic data in a multitasking manner. By incorporating frequency domain information into the loss function, the system significantly reduces reconstruction errors and improves the accuracy of predicting a characteristic operating quantity compared to traditional methods. This dual approach ensures that the compressed representation is both efficient and informative, which makes it possible to obtain improved performance in real-time applications.

According to one possibility, a method for commanding or controlling a power converter, comprises the steps described above for the method to obtain an estimation of a characteristic operating quantity \hat{η} of the candidate converter 1c, and a step DET of determining a decrease in the efficiency of the converter; in particular, the efficiency value can be compared to a threshold value or a criterion taking into account a threshold exceedance over a determined period of time.

Following the determination step, a step AL of issuing an alert to a user can be carried out. Alternatively, or additionally, a step of activating a degraded operating mode DEG of the converter can be carried out.

### Results

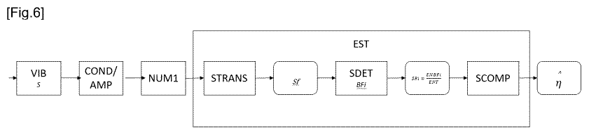

As illustrated in FIG. 6, the estimation system and method accurately predict the efficiency values, under different load conditions (from 80% to 120% of the rated load) of a converter with an average error percentage of 2.5%.

### Variants

System variants can include different types of ultrasonic probes, such as MEMS CMUT and PMUT sensors, with varying bandwidths to capture the different load operating conditions of the power converter. Another approach could involve using several ultrasonic probes positioned around the power converter to locate the ultrasonic sources by beamforming or using sensors in a phased-array configuration, which would further improve the accuracy of efficiency predictions and contribute to predictive maintenance work for fault location.

According to another variant not represented, the vibration detector can be a piezoelectric detector.

Regarding variants of the method, the variants can include the use of a smaller stride with additional layers to obtain similar compression, allowing for more accurate control of the compression ratio and potentially higher reconstruction accuracy. Another solution could involve incorporating another type of neural network, such as a recurrent neural network (RNN), for sequential data processing. This approach allows for better handling of temporal dependencies in ultrasonic data, which can improve prediction accuracy. Furthermore, the implementation of a hybrid loss function that combines time domain and frequency domain information could further reduce reconstruction errors and improve the quality of the compressed representation. Incorporating attention mechanisms into the latent space can also be considered to better capture dependencies and weighting factors, thus improving the model's ability to focus on the most relevant features of the ultrasound data.

When using a convolutional network for the autoencoder, another approach using pooling layers could be used. Pooling layers are better suited to classification tasks, as they reduce dimensionality by taking the maximum or average value within a kernel, which can, however, result in the elimination of relevant data points.

According to other variants, the characteristic operating quantity of a converter can be, for example, the output power, the state of health or the rectified current passing through the transformer, instead of, or in addition to, the efficiency.

### Method for Estimating a Characteristic Operating Quantity of a Converter by Spectral Analysis

A second embodiment of the invention is now described in which a spectral analysis method is used.

The system used is similar to that used for the first embodiment in the inference configuration. Only the method implemented by the estimation module 116 differs. The method is represented in FIG. 6.

In the case of using a spectral method, the estimation step EST of the method comprises the following sub-steps.

The first step is a step STRANS of transforming the signal S representative of the vibrations so as to obtain a frequency-domain representation Sf, for example a Fourier transform, notably to obtain a power spectral density DSP. The frequency-domain representation makes it possible to highlight the spectral characteristics related to a plurality of power ratings and a plurality of values of the characteristic operating quantity of a converter.

Indeed, each power rating or value of the characteristic operating quantity of a converter induces a specific spectral signature, manifested by a particular distribution of energy in a plurality of frequency bands BFi.

The second step is a step SDET of determining ratios Sri of the energy ENBFi contained in each of the frequency bands BFi to the total energy ENT of the signal Sf.

The bands BFi are selected so as to discriminate between the values of the considered power ratings. By calculating the ratio SRi of the energy contained in each of these bands to the total energy of the signal, it is possible to characterize the power ratings.

A third step is a step SCOMP of comparing the ratios SRi to experimentally established reference values. This comparison makes it possible to estimate the characteristic operating quantity of a converter associated with the ratios SRi. The ratios SRi correspond to power ratings.

The determination of reference values can be carried out using a system as described with reference to the first embodiment for the learning configuration. Only the method implemented by the estimation module 116 differs. In this case, reference values are stored in relation to values of the ratios SRi.

For example, four frequency bands can be defined around the following center frequencies: 116, 120, 123 and 130 kHz.

The characteristic operating quantity of a converter can be an efficiency \hat{η} of the converter, the output power, the state of health, or the rectified current passing through the transformer.

### Computer Program Product

The invention also concerns a computer program product comprising code instructions for the execution (on the data processing means 110 of the system 1) of a learning, estimation according to the first or second embodiment and/or control or command method; as well as storage means readable by computer equipment (for example, the data storage means or memory 118 of the system 1) on which this computer program product is found.

### Applications

The described method and system are particularly intended for real-time monitoring and diagnostics of power converters in various applications, including renewable energy systems, industrial power supplies, and electric vehicles. It provides accurate and non-invasive measurements of a characteristic operating quantity, enabling condition monitoring and diagnostics of power converters.

The described method and system can contribute to optimizing the design of power converters by increasing the power density of new power converters, thanks to the reduced need for bulky monitoring components. The described method and system can also contribute to optimizing the operation of converters thanks to real-time monitoring of their performance and reliability, leading to improvements in a characteristic quantity of energy efficiency and in the lifespan of the converter.

1. A method for estimating a characteristic operating quantity of a candidate power converter comprising a transformer, the method being executed by data processing circuitry, the method comprising:
acquiring a signal representative of the vibrations emitted by the transformer; and
estimating the characteristic operating quantity of the candidate power converter based on the signal representative of the detected vibrations using an inference processing of a characteristic operating quantity based on an artificial intelligence model,
wherein the method further comprises a phase of preliminarily learning the artificial intelligence model for estimating a characteristic operating quantity of a candidate power converter, comprising:
acquiring a signal representative of the vibrations emitted by the transformer of a reference converter;
acquiring at least one signal representative of at least one characteristic electrical quantity of a reference converter;
determining a calculated value of a characteristic operating quantity of the reference converter based on the at least one signal representative of at least one electrical quantity;
estimating an estimated value of a characteristic operating quantity of the reference converter based on the signal representative of the vibrations emitted by the reference transformer;
calculating a first evaluation function taking into account the calculated value of a characteristic operating quantity of the reference converter and the estimated value of a characteristic operating quantity of the reference converter; and
adjusting parameters of the artificial intelligence model using the first evaluation function.

2. The method for estimating the characteristic operating quantity of the candidate power converter according to claim 1, further comprising, prior to the estimation of a characteristic operating quantity compressing the data of the signal representative of the detected vibrations.

3. The method for estimating the characteristic operating quantity of the candidate power converter according to claim 1, further comprising performing analog-to-digital conversion of the signal representative of the vibrations into a digital signal representative of the detected vibrations.

4. The method for estimating the characteristic operating quantity of the candidate power converter according to claim 2, wherein the step of compressing the data of the signal representative of the detected vibrations is carried out using a feature extraction module.

5. The method for estimating the characteristic operating quantity of the candidate power converter according to claim 4, wherein the feature extraction module is a convolutional encoder.

6. The method for estimating the characteristic operating quantity of the candidate power converter according to claim 1, wherein the signal representative of the vibrations is an ultrasonic signal.

7. The method for estimating the characteristic operating quantity of the candidate power converter according to claim 1, further comprising conditioning and/or amplifying the signal representative of the detected vibrations.

8. The method for estimating the characteristic operating quantity of the candidate power converter according to claim 1, wherein the characteristic operating quantity of a converter is an efficiency of the converter.

9. The method according to claim 1, wherein the learning phase further comprises synchronizing the signal representative of the detected vibrations and the signal representative of at least one electrical quantity.

10. The method according to claim 1, further comprising:
compressing the signal representative of the detected vibrations using a feature extraction module, the compression step being carried out before the step of estimating the estimated value of a characteristic operating quantity of the reference converter in order to provide a version of the signal representative of the detected vibrations in a latent space;
reconstructing a reconstructed signal representative of the detected vibrations from the version of the signal representative of the detected vibrations in a latent space;
calculating a second evaluation function taking into account the reconstructed signal representative of the detected vibrations, and the version of the signal representative of the detected vibrations in a latent space; and
adjusting the parameters of the feature extraction module using the second evaluation function.

11. The method according to claim 10, wherein the step of adjusting the parameters of the feature extraction module, and the step of adjusting the parameters of the artificial intelligence model are carried out simultaneously.

12. A system for estimating a characteristic operating quantity of a power converter comprising at least one transformer, the system including a processing circuitry comprising:
an acquisition module comprising a vibration detector configured to detect vibrations emitted by the transformer and to provide a signal representative of the detected vibrations; and
a module for estimating a characteristic operating quantity of the power converter based on the signal representative of the detected vibrations,
the data processing circuitry being configured to implement the method according to claim 1.

13. The system according to claim 12, wherein the vibration detector is an ultrasonic probe.

14. The system according to claim 12, wherein the vibration detector is disposed facing the transformer of the converter.

15. The system according to claim 12, further comprising an analog-to-digital converter configured to convert the signal representative of the detected vibrations into a digital signal representative of the detected vibrations.

16. A computer program product comprising a non-transitory computer-readable medium storing code instructions for execution of the method according to claim 1, when said code instructions are executed on a computer.

17. (canceled)
